(19) United States
(12) Patent Application Publication
(10) Pub. No.: US 2026/0303056 A1
(43) Pub. Date: Oct. 1, 2026

(54) STRESS ISOLATED BULK ACOUSTIC WAVE RESONATOR DIES

(71) Applicant: TEXAS INSTRUMENTS INCORPORATED, Dallas, TX (US)

(72) Inventors: Daiki KOMATSU, Beppu-Shi Oita-Ken (JP); Kashyap MOHAN, McKinney, TX (US)

(21) Appl. No.: 19/096,382

(22) Filed: Mar. 31, 2025

(51) Int. Cl. H03H 9/02; H03H 3/02; H03H 9/05; H03H 9/10

(52) U.S. Cl. CPC H03H 9/02133; H03H 3/02; H03H 9/02102; H03H 9/0533; H03H 9/0557; H03H 9/1042

(57) ABSTRACT

In examples, a semiconductor package includes a portion of a lead frame and a controller die coupled to the portion of the lead frame. The controller die includes a first device side in which first circuitry is formed and a first non-device side opposite the first device side. The package includes a bulk acoustic wave (BAW) resonator die coupled to the controller die by a bond wire, the BAW resonator die having a second device side in which second circuitry is formed and a second non-device side opposite the second device side. The BAW resonator die includes a cavity under the second circuitry. The package includes a polymer wall contacting the second device side and circumscribing the second circuitry, and a mold compound contacting an exterior of the polymer wall and absent from a cavity defined at least in part by the polymer wall.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure is subsequently covered with a mold compound to produce a package.

### SUMMARY

In examples, a semiconductor package includes a portion of a lead frame and a controller die coupled to the portion of the lead frame. The controller die includes a first device side in which first circuitry is formed and a first non-device side opposite the first device side. The package includes a bulk acoustic wave (BAW) resonator die coupled to the controller die by a bond wire, the BAW resonator die having a second device side in which second circuitry is formed and a second non-device side opposite the second device side. The BAW resonator die includes a cavity under the second circuitry. The package includes a polymer wall contacting the second device side and circumscribing the second circuitry, and a mold compound contacting an exterior of the polymer wall and absent from a cavity defined at least in part by the polymer wall.

In examples, a method for manufacturing a semiconductor package includes etching through a thickness of a semiconductor wafer using a patterned photoresist to form multiple semiconductor dies separated by multiple gaps, each of the multiple semiconductor dies having a device side in which circuitry is formed and a non-device side opposite the device side, and each of the multiple semiconductor dies including a trench circumscribing the circuitry and a cavity in that semiconductor die between the circuitry of that semiconductor die and the non-device side of that semiconductor die. The method also includes depositing a polymer material into the multiple gaps and on the non-device sides of the semiconductor dies, and dicing through the polymer material in one of the multiple gaps to produce a first semiconductor die separate from the remaining ones of the multiple semiconductor dies. The method includes coupling a second semiconductor die to a portion of a lead frame, coupling the first semiconductor die to the second semiconductor die, and applying a mold compound to the portion of the lead frame, the second semiconductor die, and the first semiconductor die.

### BRIEF DESCRIPTION OF THE DRAWINGS

FIGS. 1A, 1B, and 1C are profile cross-sectional, top-down, and perspective views of a semiconductor package including a stress isolated bulk acoustic wave (BAW) resonator die, in accordance with various examples.

FIGS. 2A, 2B, and 2C are profile cross-sectional, top-down, and perspective views of a semiconductor package including a stress isolated BAW resonator die, in accordance with various examples.

FIGS. 3A, 3B, and 3C are profile cross-sectional, top-down, and perspective views of a semiconductor package including a stress isolated BAW resonator die, in accordance with various examples.

FIGS. 4A, 4B, and 4C are profile cross-sectional, top-down, and perspective views of a semiconductor package including a stress isolated BAW resonator die, in accordance with various examples.

FIG. 5 is a flow diagram of a method for manufacturing a semiconductor package including a stress isolated BAW resonator die, in accordance with various examples.

FIGS. 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, and 17C are a process flow for manufacturing a semiconductor package including a stress isolated BAW resonator die, in accordance with various examples.

### DETAILED DESCRIPTION

Stress isolation and mechanical stress management are critical challenges in semiconductor packaging, particularly for bulk acoustic wave (BAW) resonator dies, which are highly sensitive to mechanical deformation. BAW resonators rely on precisely controlled acoustic wave propagation within a piezoelectric layer sandwiched between electrodes, and any external mechanical stress can alter their resonant frequency, degrade performance, or even induce long-term reliability issues. Unlike typical integrated circuits (ICs), BAW devices operate at extremely high frequencies (GHz range), making them more susceptible to variations in mechanical stress, temperature fluctuations, and packaging-induced warping. Stress from encapsulation, molding compounds, or mismatched thermal expansion coefficients between materials can lead to frequency drift, phase noise degradation, and shifts in the electromechanical coupling efficiency. These effects are especially problematic in radio frequency (RF) filters for mobile and wireless communications, where frequency precision is paramount. Additionally, as package sizes shrink and integration levels increase (e.g., multi-chip modules or system-in-package designs), mechanical stress effects become more pronounced due to the tighter constraints on die placement and thermal cycling conditions.

This description provides various examples of a semiconductor package including stress isolated BAW resonator dies. More specifically, the semiconductor packages described herein include one or more structural features that protect the BAW resonator element (e.g., piezoelectric element) from mechanical stress introduced by various sources, such as those described above. In examples, a semiconductor package includes a portion of a lead frame and a first semiconductor die coupled to the portion of the lead frame. The first semiconductor die has a first device side in which first circuitry is formed and a first non-device side opposite the first device side. The package also includes a second semiconductor die coupled to the first device side of the first semiconductor die. The second semiconductor die has a second device side in which second circuitry is formed and a second non-device side opposite the second device side. The second semiconductor die has four lateral surfaces orthogonal to the second device side. The package further includes a polymer coat physically contacting the four lateral surfaces and the second non-device side. The polymer coat does not cover an entirety of the second device side. The package includes a trench in the second device side and circumscribing the second circuitry, and a cavity in the second semiconductor die and below the second circuitry. The package includes a polymer wall circumscribing the trench and extending vertically away from the second device side, and a mold compound covering the first and second semiconductor dies and physically contacting an outer surface of the polymer wall. The package further includes an epoxy film contacting a top surface of the polymer wall and a top surface of the mold compound. These above-described structural features help to isolate the BAW resonator element from external influences, particularly mechanical stress, that would adversely impact operation. In this way, these structural features mitigate deleterious effects such as frequency drift, phase noise degradation, and shifts in the electromechanical coupling efficiency.

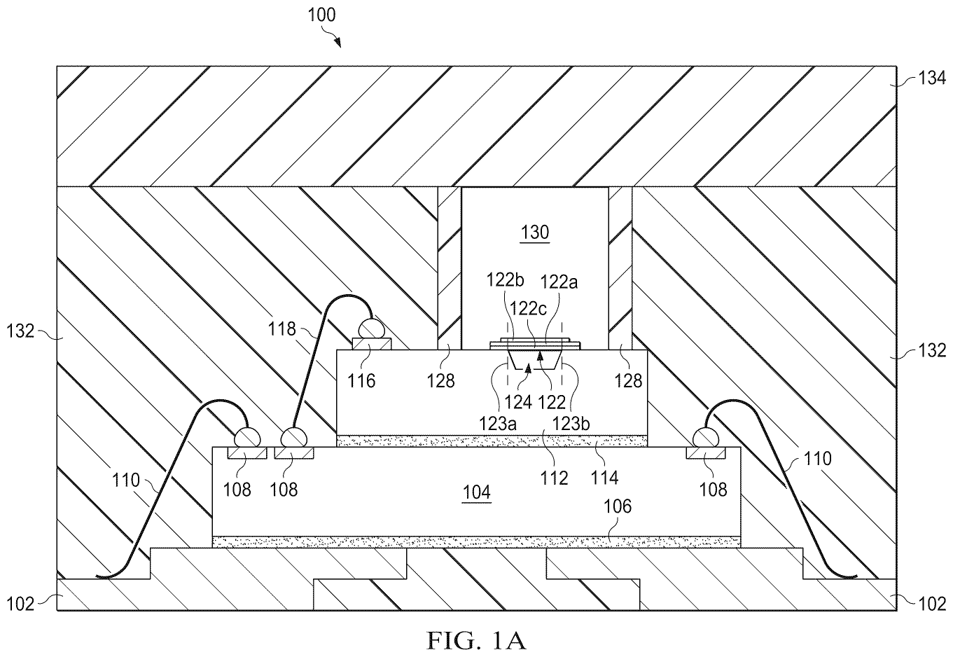

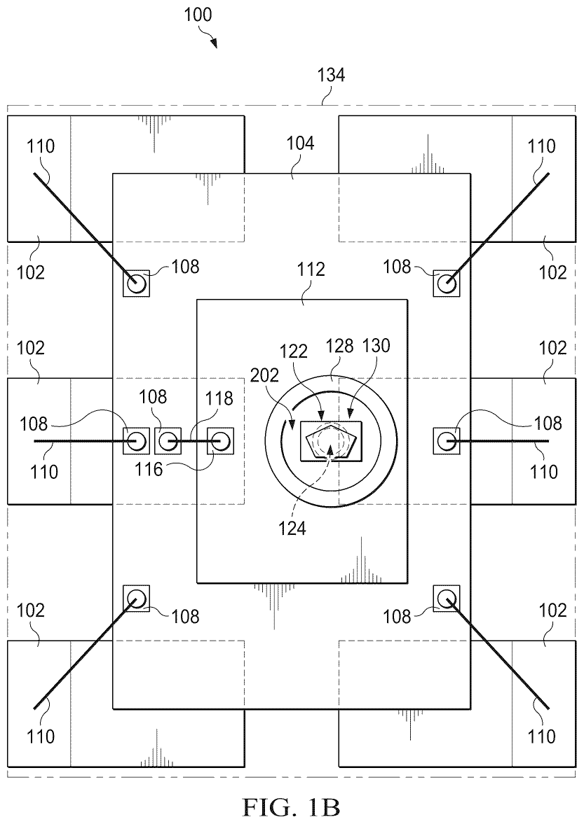

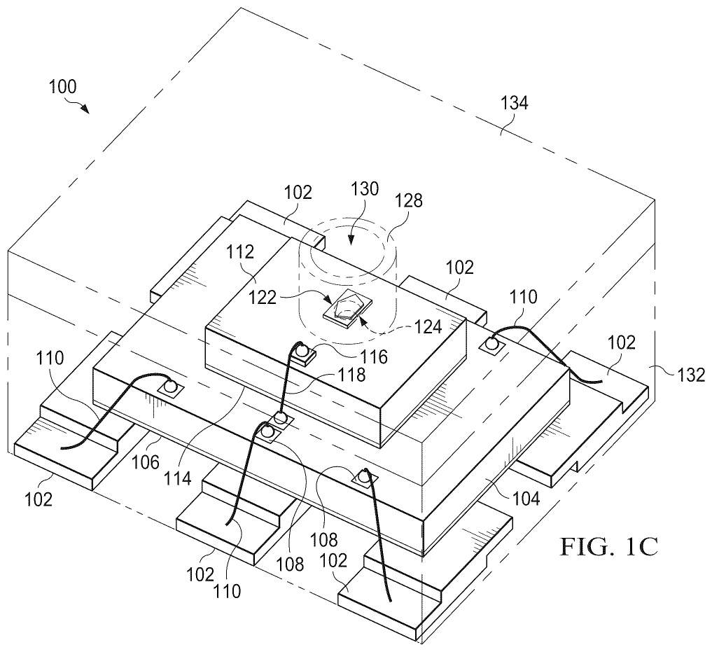

FIGS. 1A, 1B, and 1C are profile cross-sectional, top-down, and perspective views of a semiconductor package 100 including a stress isolated bulk acoustic wave (BAW) resonator die, in accordance with various examples. In particular, the example semiconductor package 100 includes a portion of a lead frame including multiple conductive terminals 102. The conductive terminals 102 may be of any suitable type, such as conductive terminals that may be included in a quad flat no lead (QFN) package, gullwing style leads, etc. The semiconductor package 100 includes a semiconductor die 104 coupled to one or more of the conductive terminals 102 by a suitable die attach material 106. The semiconductor die 104 may include a device side facing upward and away from the conductive terminals 102, and a non-device side that is opposite the device side and that faces toward the conductive terminals 102. The device side of the semiconductor die 104 has circuitry formed therein that may be configured to perform one or more operations. For example, the circuitry of the semiconductor die 104 may be configured to operate a BAW semiconductor die coupled to the semiconductor die 104, as described below.

Bond pads 108 may be present on the device side of the semiconductor die 104. Bond wires 110 couple the bond pads 108 to the various conductive terminals 102. A semiconductor die 112 (e.g., a BAW resonator die) is coupled to the device side of the semiconductor die 104 by way of a suitable die attach material 114. The semiconductor die 112 includes a device side in which circuitry is formed and that faces away from the semiconductor die 104, and a non-device side opposite the device side and facing toward the semiconductor die 104. The device side of the semiconductor die 112 includes multiple bond pads 116. Bond wires 118 couple the bond pads 116 to the device side of the semiconductor die 104. In examples, the bond pads 108 outnumber the bond pads 116.

A resonator element 122 is coupled to the device side of the semiconductor die 112 and is suspended over a cavity 124 (e.g., a cavity containing air) in the device side of the semiconductor die 112. The resonator element 122 may include a piezoelectric layer 122a (e.g., aluminum nitride, scandium-doped aluminum nitride) sandwiched between a pair of electrodes 122b, 122c (e.g., molybdenum, tungsten, aluminum). The cavity 124 extends from vertical plane 123a to vertical plane 123b in the profile cross-sectional view, and the resonator element 122 extends horizontally beyond the vertical planes 123a and 123b in the profile cross-sectional view. A depth of the cavity 124 in a side view ranges from 40 microns to 60 microns, with a depth below this range being disadvantageous because of a resulting unacceptable degree of mechanical stress, and with a depth above this range being disadvantageous because of a substantial decrease in manufacturing efficiency. A horizontal width of the cavity 124 in a top-down view ranges from 200 microns to 300 microns, with a width below this range being disadvantageous because of acoustic leakage, and with a width above this range being disadvantageous because of the resulting mechanical stress or weakness in the die. A polymer wall 128 (e.g., a cylindrical polymer wall) is on the device side of the semiconductor die 112 and circumscribes the resonator element 122. The polymer wall 128 defines a cavity 130 that contains air. A mold compound 132 physically contacts an exterior surface of the polymer wall 128 and is not present in the cavity 130. An epoxy film 134 physically contacts a top surface of the polymer wall 128 and a top surface of the mold compound 132.

A horizontal distance between the inner surface of the polymer wall 128 and the closest portion of the resonator element 122 is at least 10 microns, with a distance below this range being disadvantageous because it results in cracks in the resonator package membrane. A horizontal diameter of the polymer wall 128 measured from inner surface to inner surface ranges from 200 microns to 300 microns. The polymer wall 128 has a height ranging from 100 microns to 150 microns, with a height below this range being disadvantageous because of the increased need for wire height control, and with a height above this range being disadvantageous because mold compound cavities form as a result. The polymer wall 128 may be composed of any suitable material, such as epoxy photo imageable materials. Although the polymer wall 128 is depicted as being cylindrical, other shapes are contemplated. For example, the polymer wall 128 may have a horizontal cross-sectional shape that is rectangular or otherwise polygonal, triangular, ovoid, etc. The epoxy film 134 has a vertical thickness ranging from 50 microns to 80 microns, with a thickness below this range being disadvantageous because of the resulting high risk of film tenting, and with a thickness above this range being disadvantageous because of unacceptably decreased manufacturing efficiency. The epoxy film 134 may be composed of any suitable material, such as AJINOMOTO® build-up film (ABF), SU-8 film, etc.

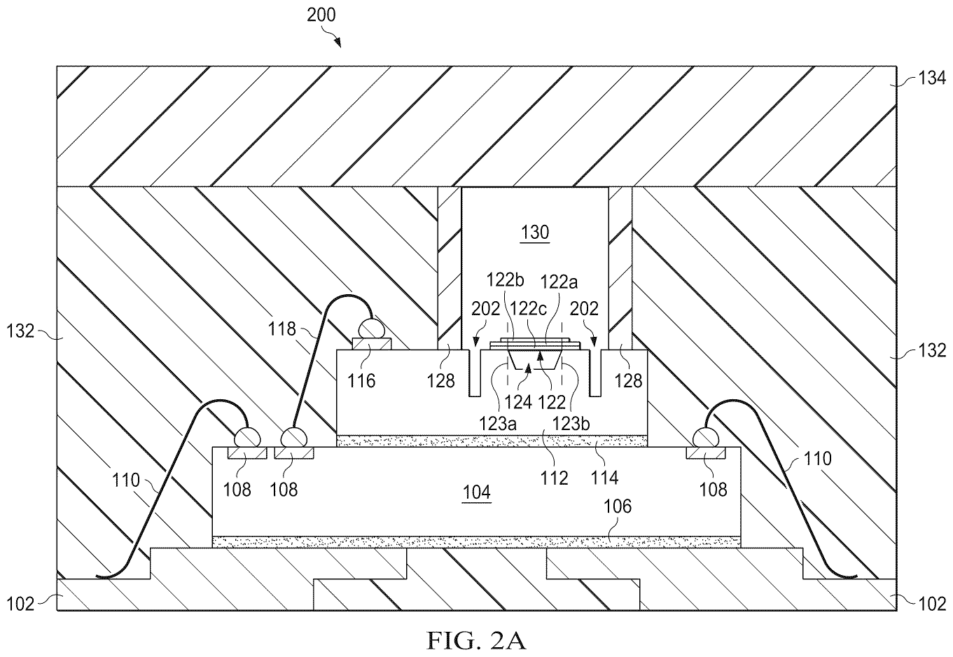

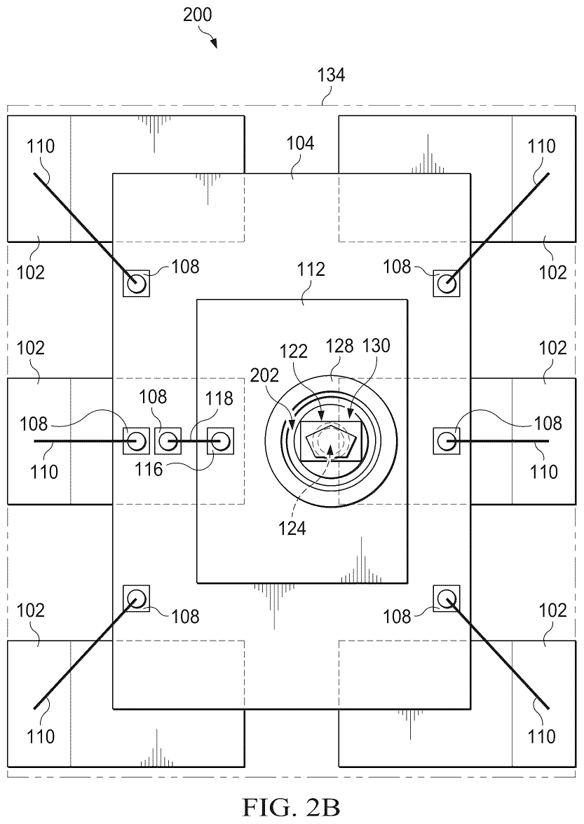

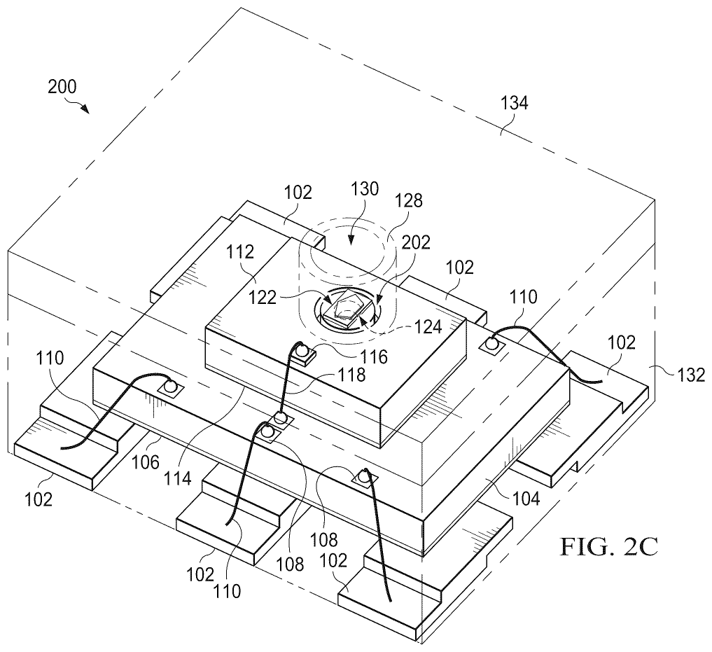

FIGS. 2A, 2B, and 2C are profile cross-sectional, top-down, and perspective views of a semiconductor package 200 including a stress isolated BAW resonator die, in accordance with various examples. The semiconductor package 200 is identical to the semiconductor package 100 of FIGS. 1A-1C, except that the semiconductor die 112 of the semiconductor package 200 includes a trench 202 that surrounds the resonator element 122 and the cavity 124. The trench 202 mitigates the mechanical stress that reaches and affects the resonator element 122, thereby increasing the stress isolation provided to the resonator element 122. The trench 202 extends vertically downward a distance from the horizontal plane in which the resonator element 122 lies, where the distance ranges from 10 microns to 20 microns, with a distance below this range being disadvantageous because of the increase in mechanical stress, and with a distance above this range being disadvantageous because of an unacceptable decrease in manufacturing efficiency. This depth of the trench 202 is at least 20% of the thickness of the semiconductor die 112, with a depth below this range being disadvantageous because of the increase in mechanical stress. A horizontal distance between an edge of the resonator element 122 and an edge of the trench 202 ranges from 200 microns to 300 microns, with a distance below this range being disadvantageous because of increased mechanical stress, and with a distance above this range being disadvantageous because of an unacceptable decrease in manufacturing efficiency. A horizontal distance between an edge of the trench 202 and the inner surface of the polymer wall 128 is at least 50 microns, with a distance below this range being disadvantageous because the risk of collapse during application of the mold compound is significantly increased.

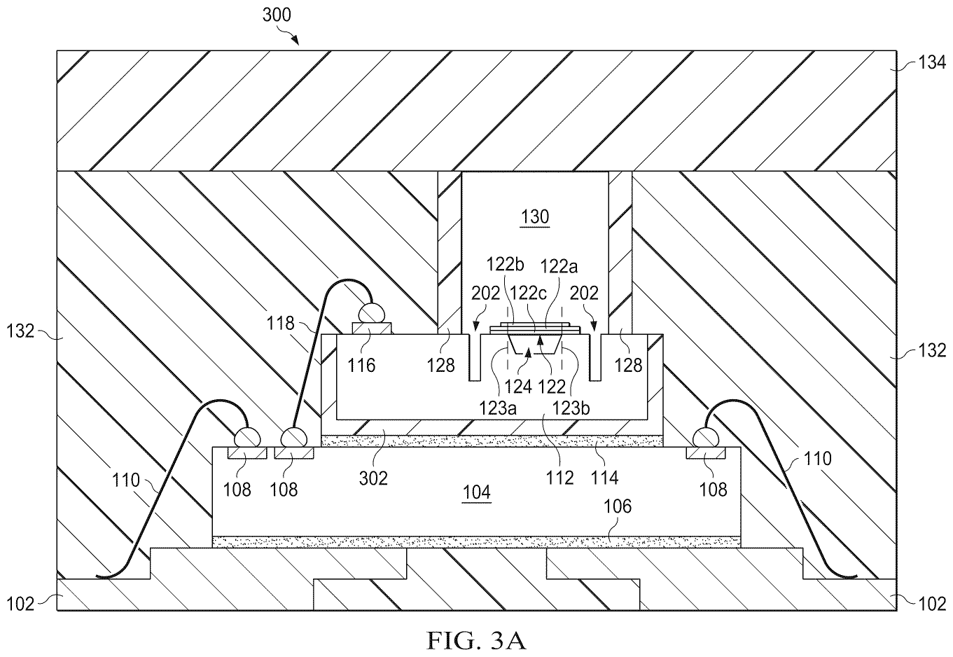

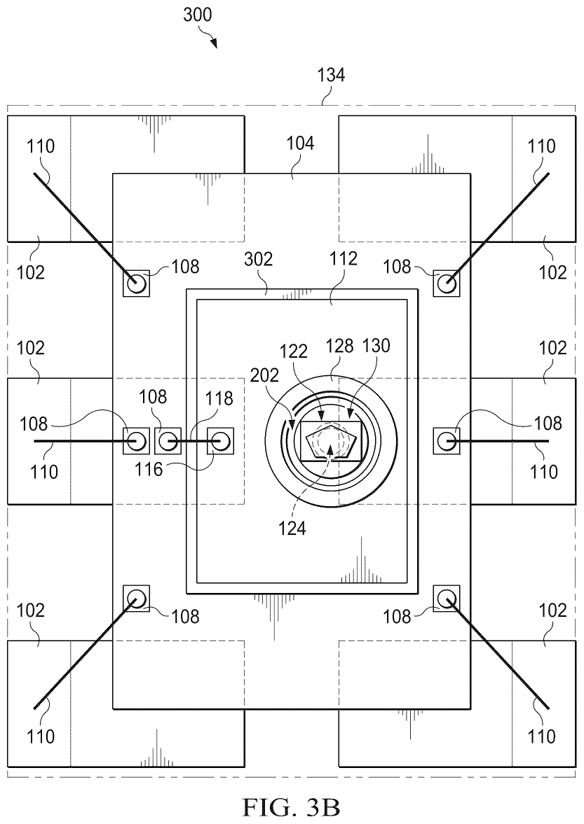

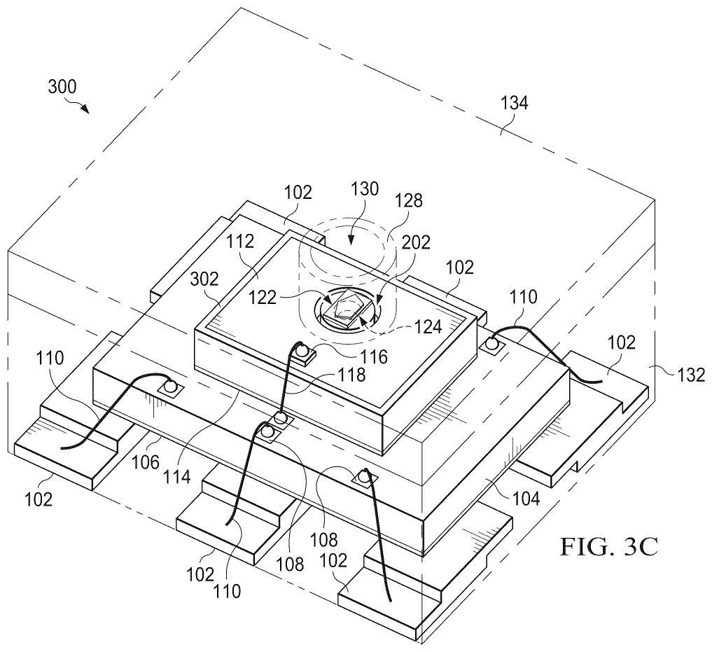

FIGS. 3A, 3B, and 3C are profile cross-sectional, top-down, and perspective views of a semiconductor package 300 including a stress isolated BAW resonator die, in accordance with various examples. The semiconductor package 300 is identical to the semiconductor package 200 of FIGS. 2A-2C, except that the semiconductor package 300 includes a polymer coat 302 that physically contacts multiple surfaces of the semiconductor die 112. More specifically, the polymer coat 302 physically contacts the non-device side of the semiconductor die 112 and the four lateral surfaces of the semiconductor die 112 that are orthogonal to the non-device side of the semiconductor die 112. The polymer coat 302 may be composed of any suitable material, such as epoxy photo imageable materials. The polymer coat 302 has a thickness ranging from 10 microns to 15 microns, with a thickness below this range being disadvantageous because of an increase in mechanical stress, and with a thickness above this range being disadvantageous because of significant challenges in material filling, such as the presence of voids in the volumes occupied by the polymer coat 302 as the polymer coat 302 is applied. In examples, the polymer coat 302 does not physically contact an entirety of the device side of the semiconductor die 112. In examples, the polymer coat 302 does not physically contact any of the device side of the semiconductor die 112.

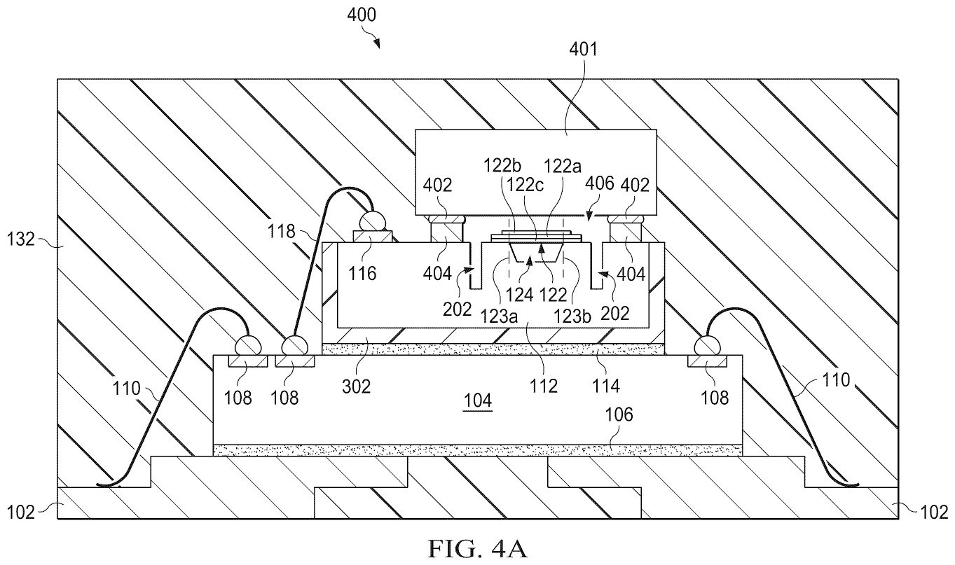

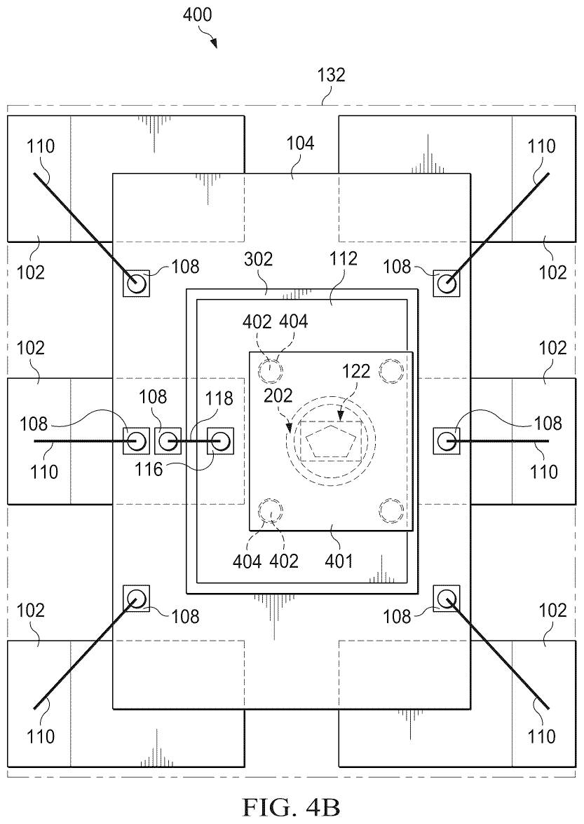

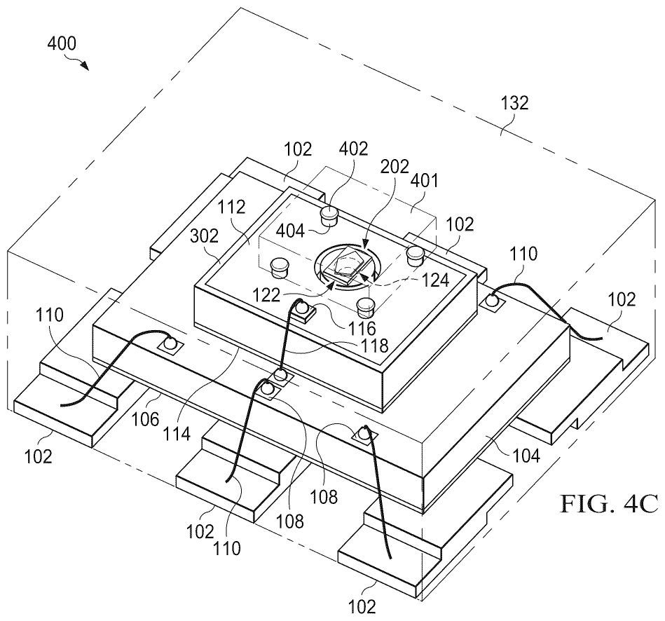

FIGS. 4A, 4B, and 4C are profile cross-sectional, top-down, and perspective views of a semiconductor package 400 including a stress isolated BAW resonator die, in accordance with various examples. The semiconductor package 400 is identical to the semiconductor package 300 of FIGS. 3A-3C, except that the semiconductor package 400 lacks the polymer wall 128 and the epoxy film 134. Further, the semiconductor package 400 includes a cap 401 (e.g., a semiconductor cap, such as a silicon cap), a metal (e.g., copper) contact 402 on the cap 401 (e.g., extending along an entire perimeter of a bottom surface of the cap 401) and facing the semiconductor die 112, and one or more solder bumps 404 coupling the metal contact 402 to the device side of the semiconductor die 112. The combination of the metal contact 402 and the solder bumps 404 creates a clearance between the device side of the semiconductor die 112 and the bottom surface of the cap 401 facing the semiconductor die 112. This clearance results in a cavity 406, which may contain air, for example. The mold compound 132 physically contacts the top and lateral surfaces of the cap 401. The mold compound 132 may physically contact portions, but not all, of the bottom surface of the cap 401. The horizontal distance between an edge of the trench 202 and a solder bump 404 ranges between 20 microns and 30 microns, with a distance below this range being disadvantageous because the resultant gaps are inadequately large to maintain low levels of mechanical stress, and with a distance above this range being disadvantageous because it results in an unacceptably large semiconductor package size. The vertical height (i.e., clearance) of the cavity 406 ranges from 400 microns to 500 microns, with a height below this range being disadvantageous because the resultant gaps are inadequately large to maintain low levels of mechanical stress, and with a height above this range being disadvantageous because it results in an unacceptably large semiconductor package size. The cavity 406 is in fluid communication with the trench 202. The thickness of the cap 401 ranges from 100 microns to 150 microns, with a thinner cap inadequately protecting the resonator element from mechanical stress, and with a thicker cap increasing package size to an unacceptable degree.

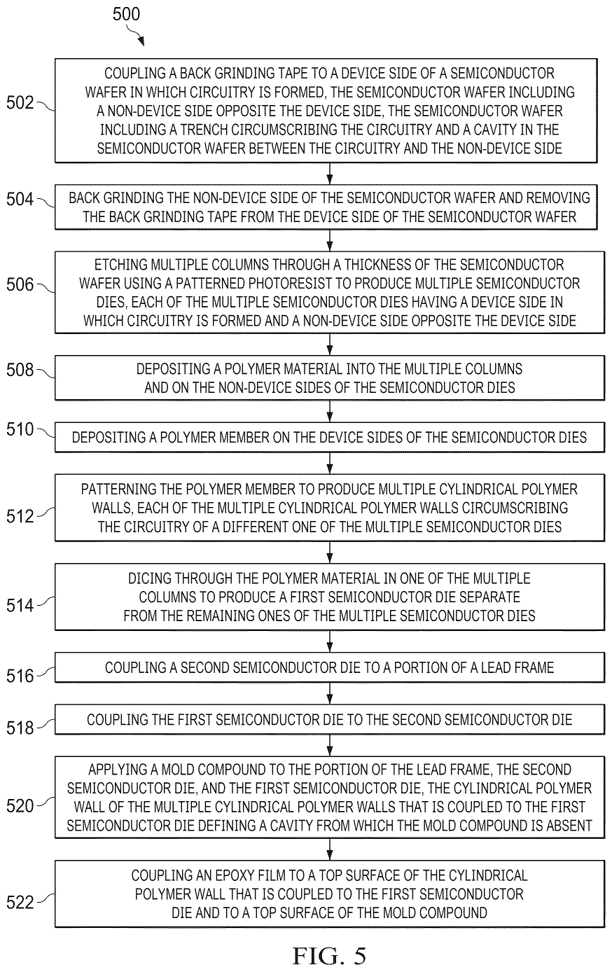

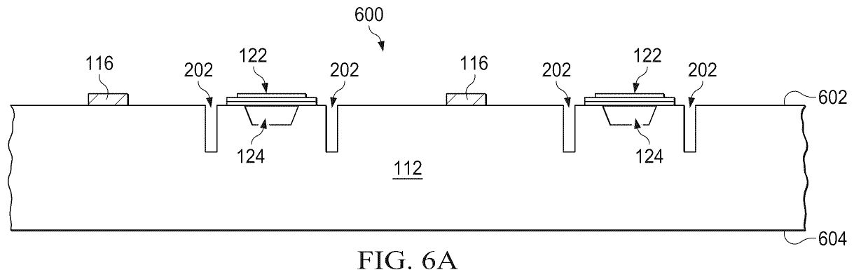

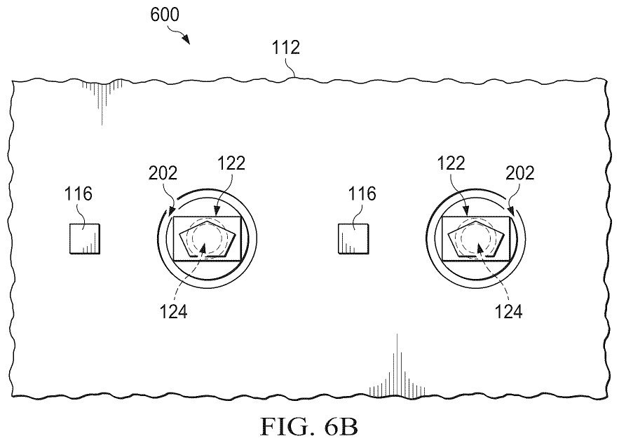

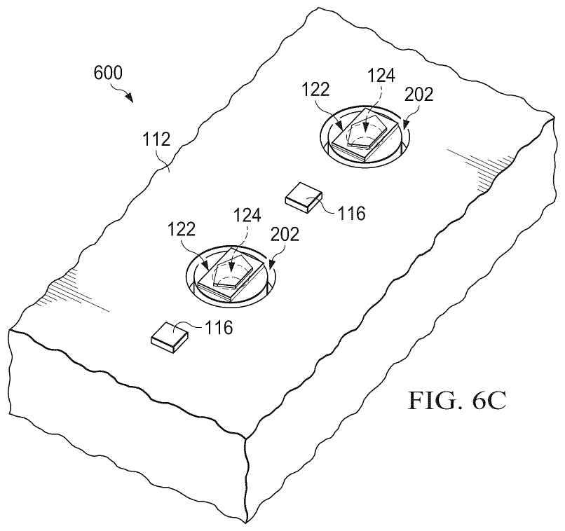

FIG. 5 is a flow diagram of a method 500 for manufacturing a semiconductor package including a stress isolated BAW resonator die, in accordance with various examples. FIGS. 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, and 17C are a process flow for manufacturing a semiconductor package including a stress isolated BAW resonator die, in accordance with various examples. Accordingly, FIGS. 5 and 6A-17C are now described in parallel with each other.

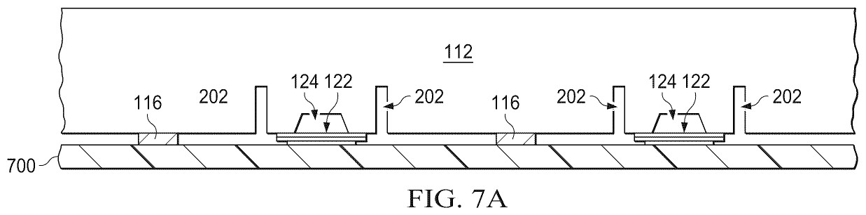

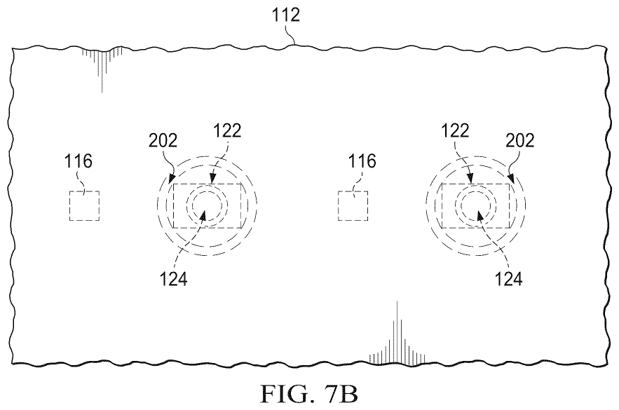

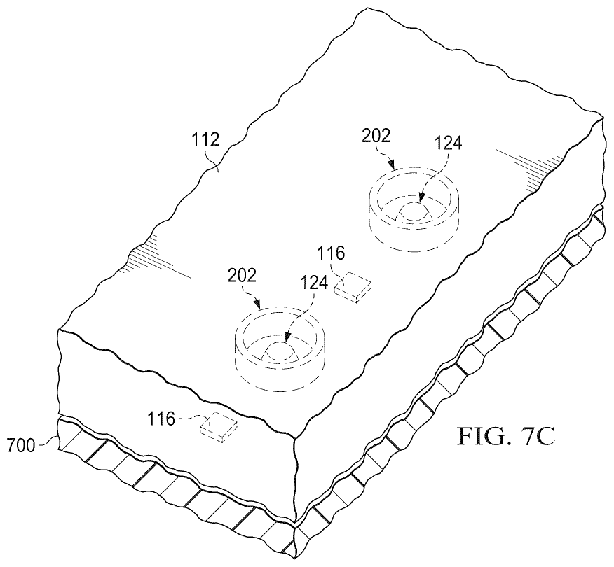

The method 500 includes coupling a back grinding tape to a device side of a semiconductor wafer in which circuitry is formed (502). The semiconductor wafer includes a non-device side opposite the device side and further includes a trench circumscribing both the circuitry and a cavity in the semiconductor wafer that is between the circuitry and the non-device side (502). FIGS. 6A-6C are profile cross-sectional, top-down, and perspective views of a semiconductor wafer 600 (e.g., a silicon wafer, a gallium nitride wafer). The semiconductor wafer 600 includes a device side 602 and a non-device side 604. Circuitry is formed in the device side 602. The device side 602 includes resonator elements 122 and cavities 124 between the resonator elements 122 and the non-device side 604. Bond pads 116 are present on the device side 602. Trenches 202 are also present in the device side 602. FIGS. 7A-7C are profile cross-sectional, top-down, and perspective views of the structure of FIGS. 6A-6C, except that a back grinding tape 700 has been coupled to the device side 602 of the semiconductor wafer 600.

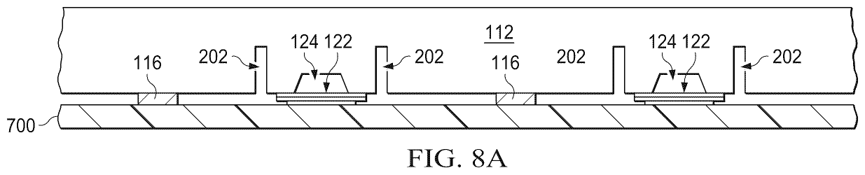

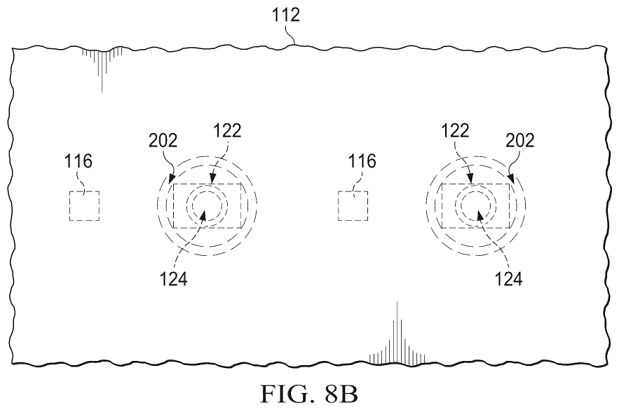

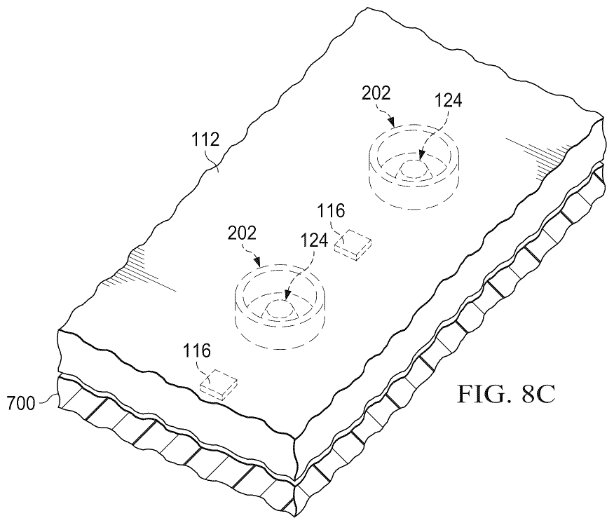

The method 500 includes back grinding the non-device side of the semiconductor wafer and removing the back grinding tape from the device side of the semiconductor wafer (504). FIGS. 8A-8C are profile cross-sectional, top-down, and perspective views of the structure of FIGS. 7A-7C, except that the non-device side 604 of the semiconductor wafer 600 has been grinded to thin the semiconductor wafer 600. The back grinding tape 700 is subsequently removed.

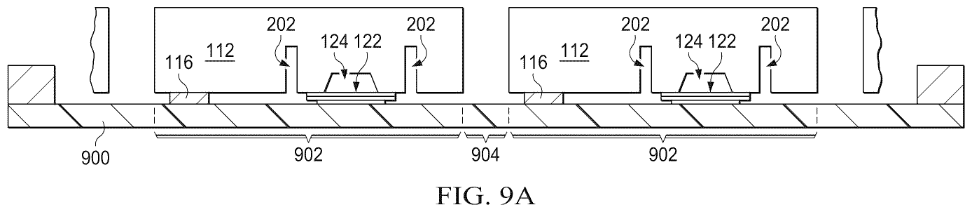

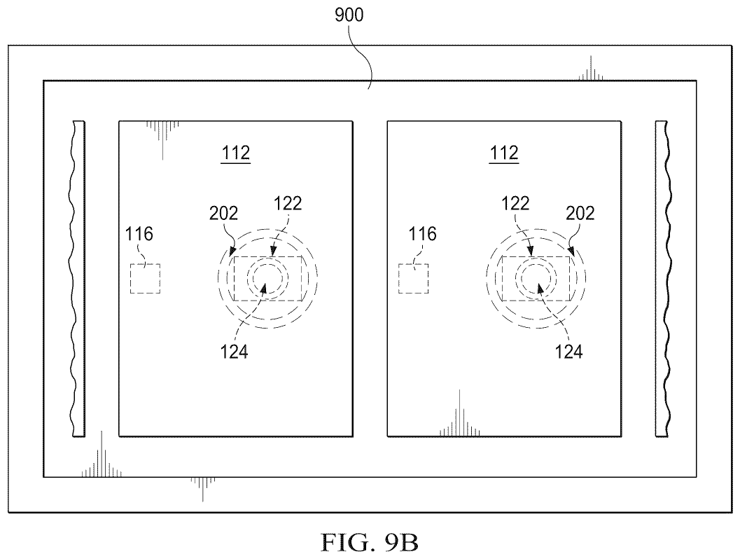

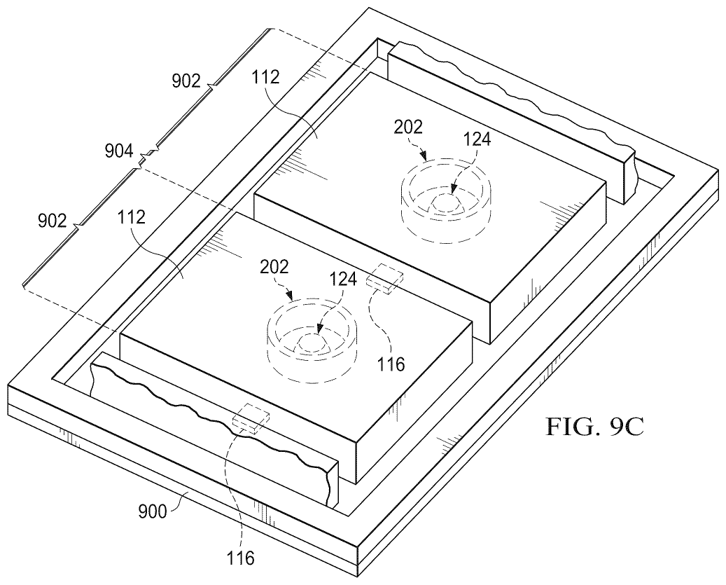

The method 500 includes etching multiple columns through a thickness of the semiconductor wafer using a patterned photoresist to produce multiple semiconductor dies (506). Each of the multiple semiconductor dies has a device side in which circuitry is formed and a non-device side opposite the device side (506). FIGS. 9A-9C are profile cross-sectional, top-down, and perspective views of the structure of FIGS. 8A-8C, except that the device side 602 of the semiconductor wafer 600 has been coupled to a dicing tape 900, and the semiconductor wafer 600 has been singulated (e.g., sawn) into individual semiconductor dies 902 separated from each other by gaps 904. Each of the gaps 904 has a width in the horizontal direction ranging from 10 microns to 15 microns, with a width below this range being disadvantageous because dry etching becomes technically challenging, and with a width above this range being disadvantageous because it results in an unacceptably high degree of silicon chipping. Each of the gaps 904 extends through an entire vertical thickness of the semiconductor wafer 600, as shown.

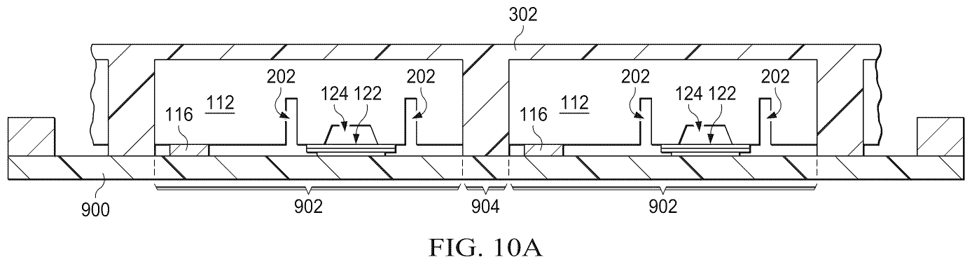

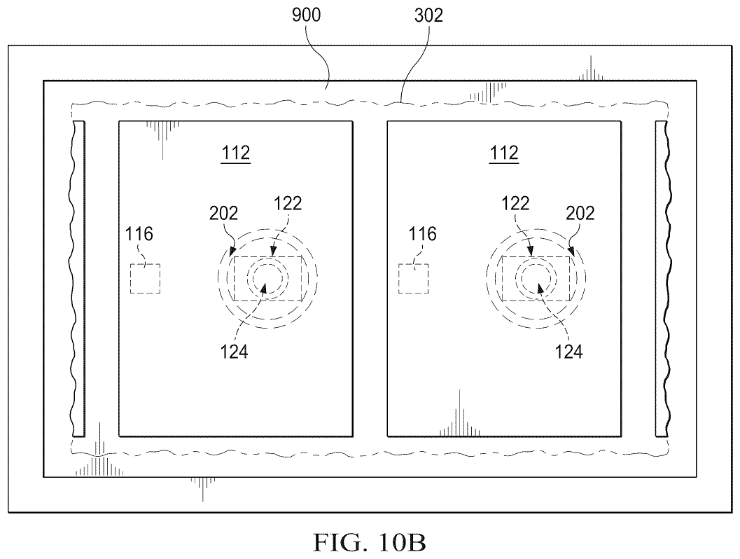

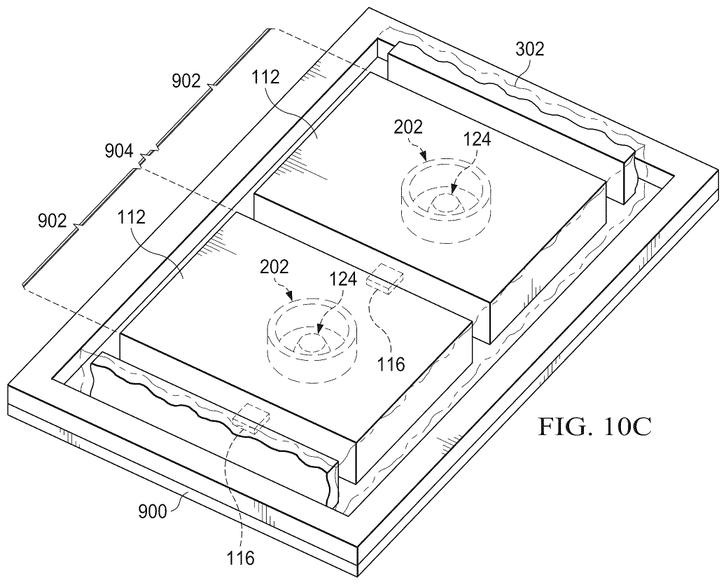

The method 500 includes depositing a polymer material into the multiple columns and on the non-device sides of the semiconductor dies (508). The polymer material may be any suitable polymer material, such as SU-8 epoxy material. In examples, the polymer material has a low modulus of at least 1.5 GPa, with a modulus below this range being disadvantageous because it risks polymer collapse during the mold compound application process. The polymer material may be deposited by any suitable technique, such as spin coating. FIGS. 10A-10C are profile cross-sectional, top-down, and perspective views of the structure of FIGS. 9A-9C, except that the polymer coat 302 has been applied to and in between the multiple semiconductor dies 902 as described and as shown.

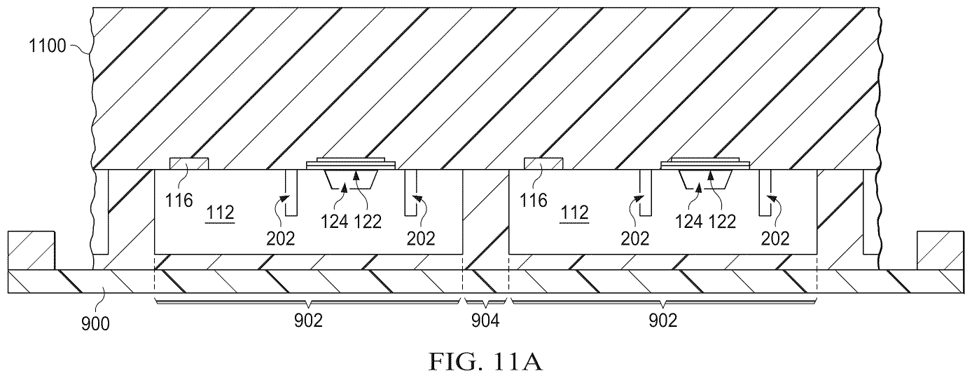

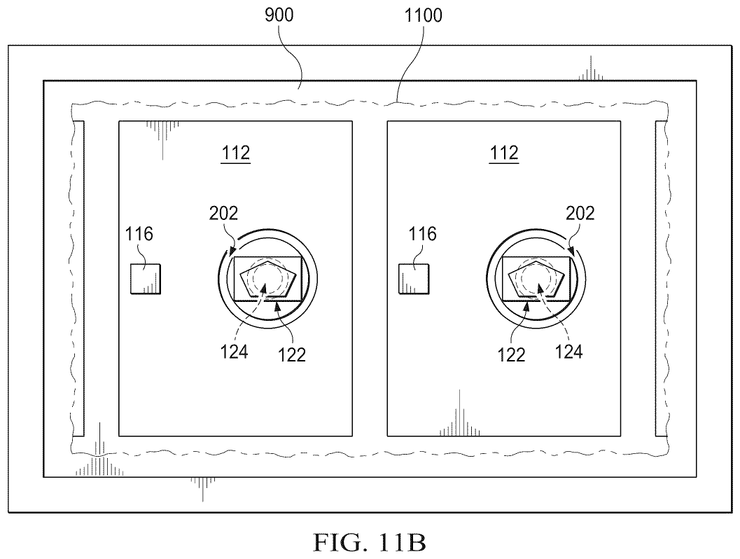

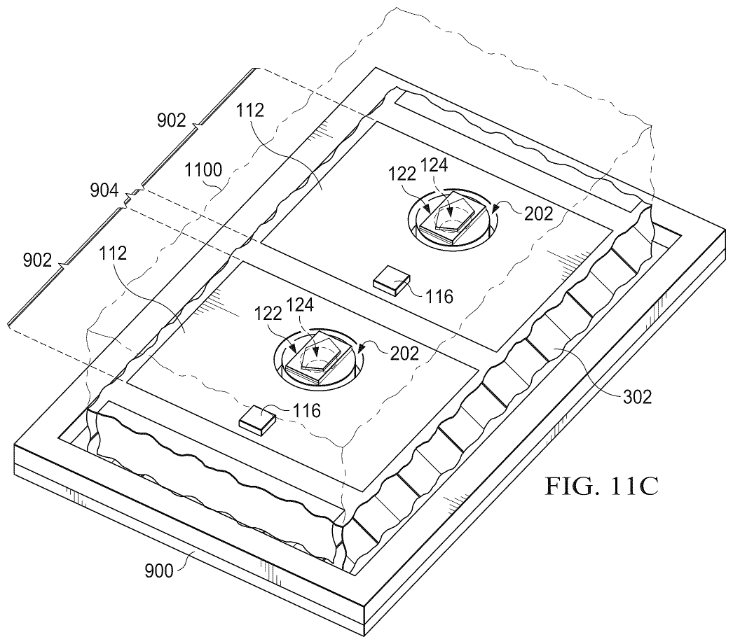

The method 500 includes depositing a polymer member on the device sides of the semiconductor dies (510). FIGS. 11A-11C are profile cross-sectional, top-down, and perspective views of the structure of FIGS. 10A-10C, except that a polymer member 1100 is applied to the device sides of the multiple semiconductor dies 902. Because the polymer wall 128 is formed from the polymer member 1100, the polymer member 1100 has a vertical thickness that is the same as the vertical height of the polymer wall 128, described above. For the same reason, the polymer member 1100 is formed of the same material as the polymer wall 128 and as described above.

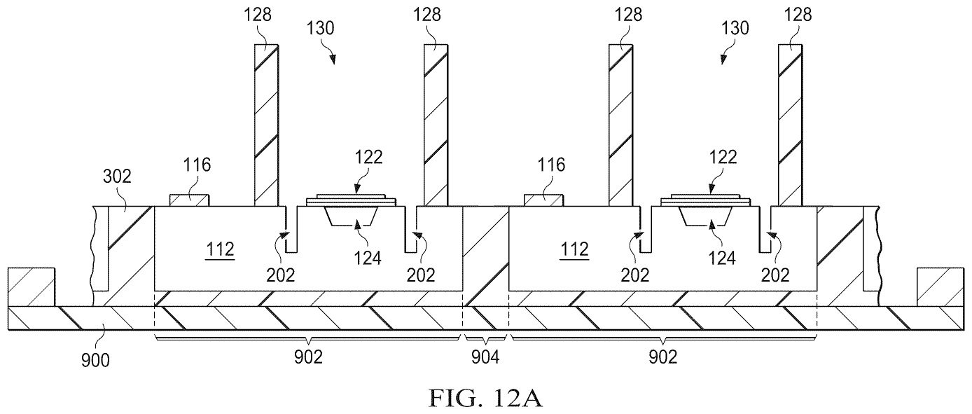

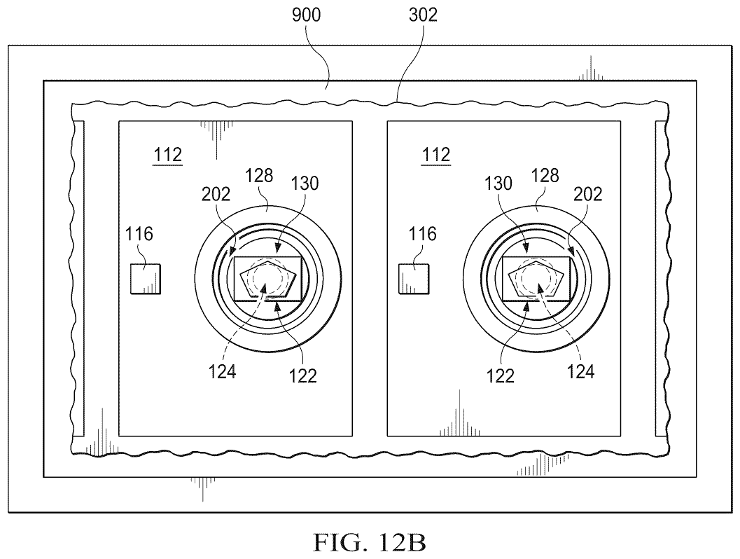

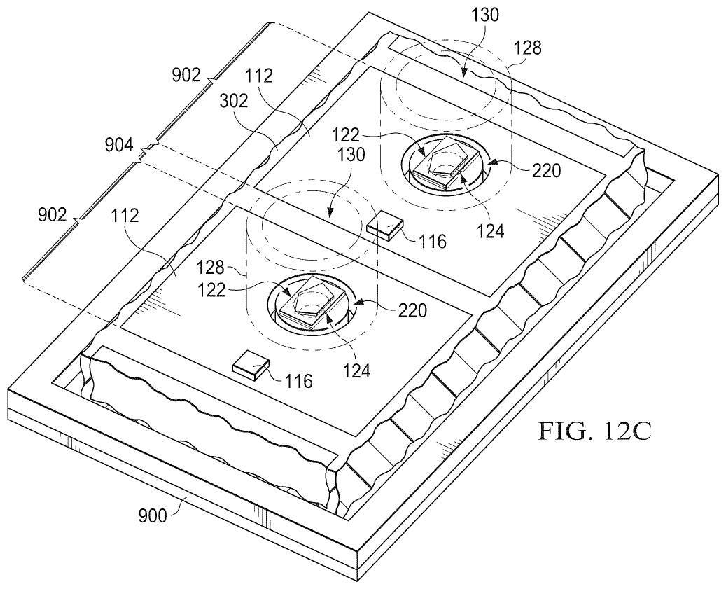

The method 500 includes patterning the polymer member to produce multiple cylindrical polymer walls, with each of the cylindrical polymer walls circumscribing the circuitry of a different one of the multiple semiconductor dies (512). FIGS. 12A-12C are profile cross-sectional, top-down, and perspective views of the structure of FIGS. 11A-11C, except that the polymer member 1100 has been patterned by appropriate photolithography processes (e.g., using a patterned mask, light to expose the polymer member 1100, a chemical solvent to develop the exposed portions of the polymer member 1100), etching techniques, etc. The patterning process results in a structure that is similar or identical to the polymer wall 128.

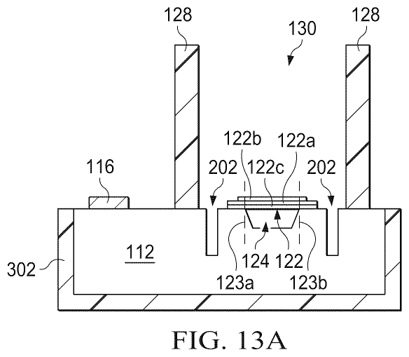

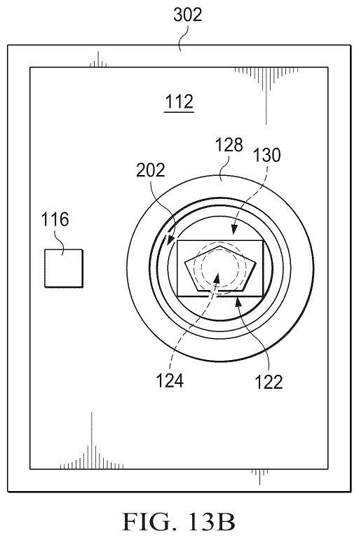

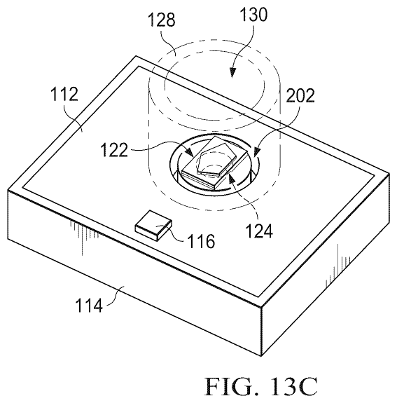

The method 500 includes dicing through the polymer material in one of the multiple columns to produce a first semiconductor die separate from the remaining ones of the multiple semiconductor dies (514). FIGS. 13A-13C are profile cross-sectional, top-down, and perspective views of the structure of FIGS. 12A-12C, except that the structure has been diced (cut) through the portions of the polymer coat 302 that is present inside the gaps 904 and vertically aligned with the gaps 904. The structure may be diced by mechanical sawing, for example. The dicing produces multiple instances of the structure shown in FIGS. 13A-13C.

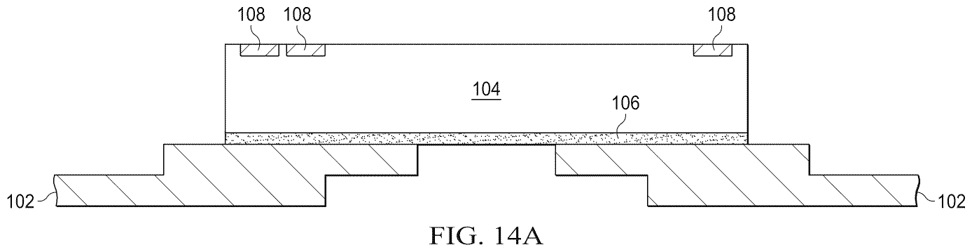

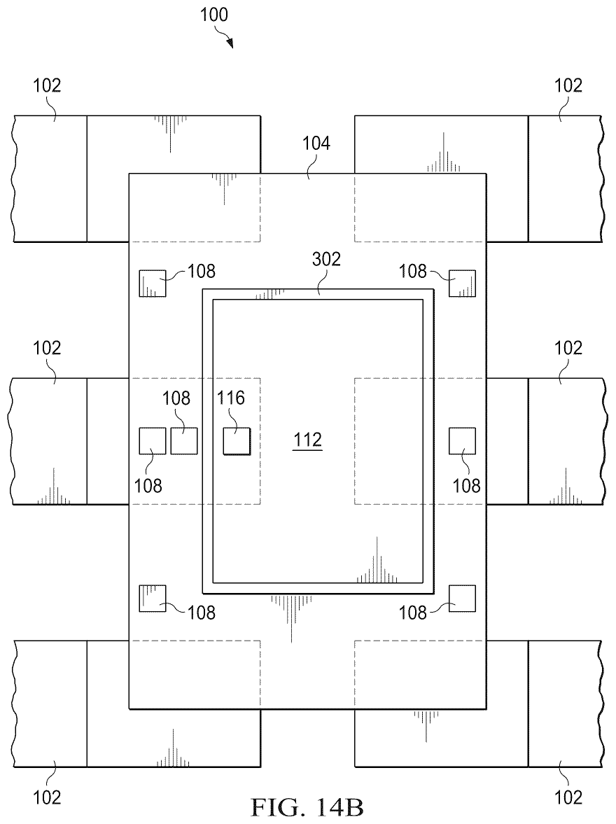

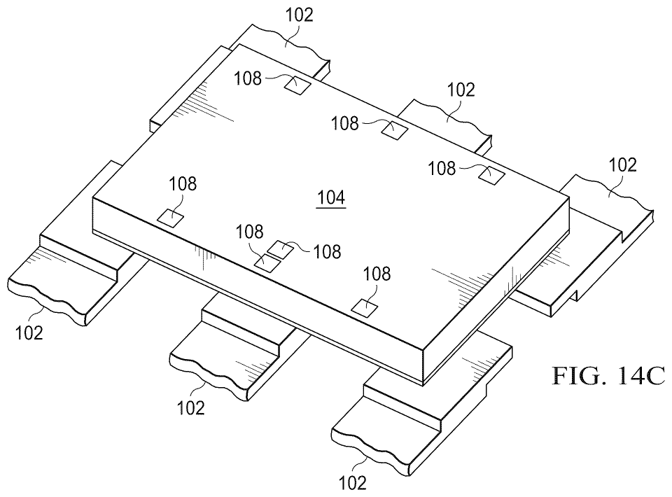

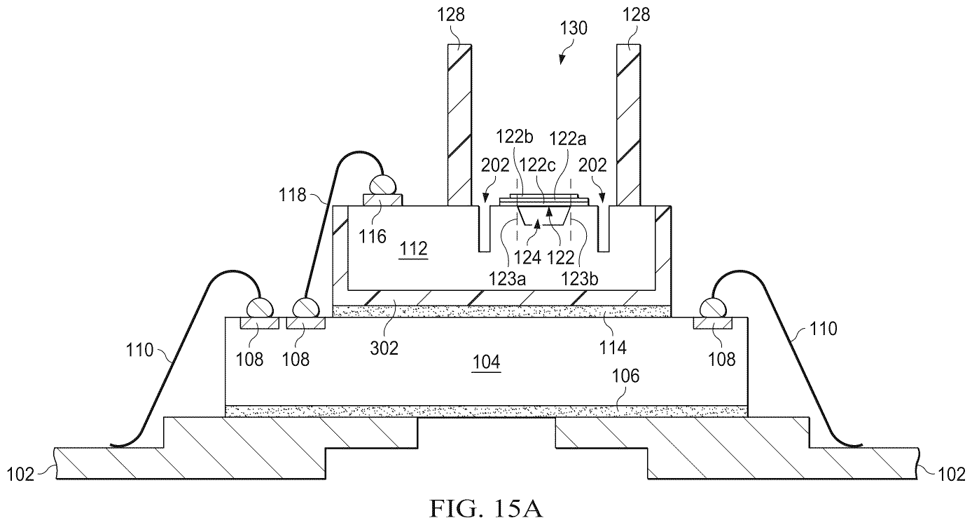

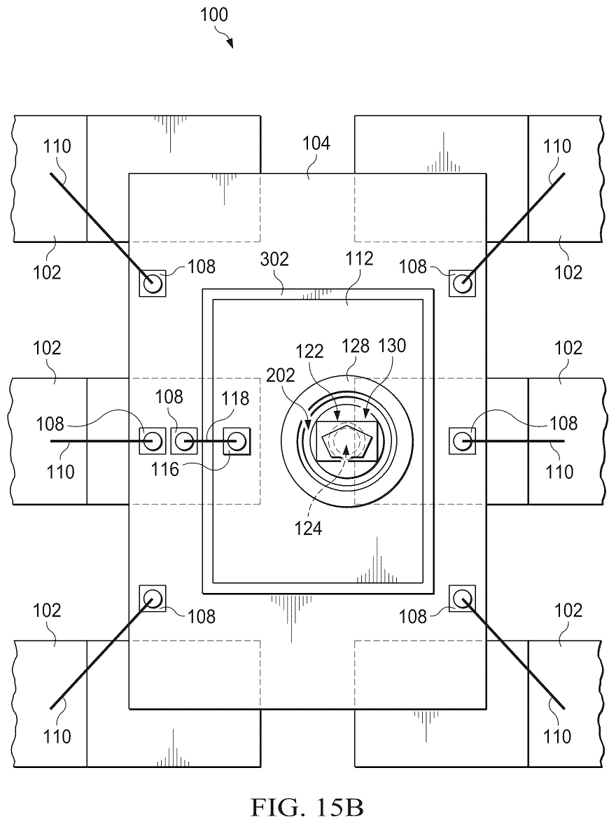

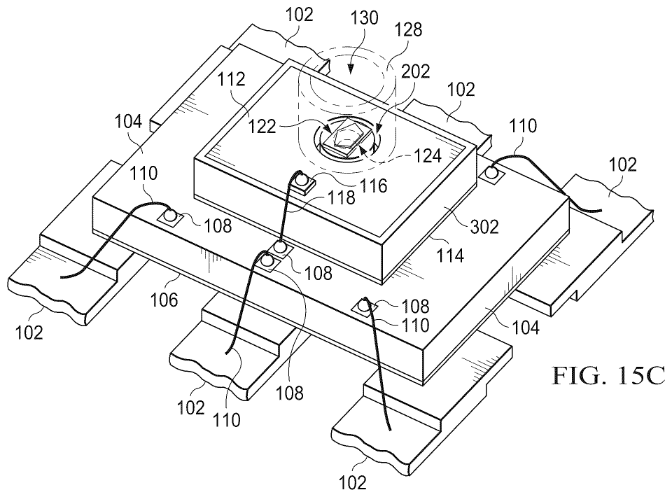

The method 500 includes coupling a second semiconductor die to a portion of a lead frame (516). FIGS. 14A-14C are profile cross-sectional, top-down, and perspective views of a portion of a lead frame that includes multiple conductive terminals 102 and the semiconductor die 104 coupled to the conductive terminals 102 by die attach material 106. The method 500 includes coupling a first semiconductor die to the second semiconductor die (518). FIGS. 15A-15C are profile cross-sectional, top-down, and perspective views of the structure of FIGS. 14A-14C, except that the structure of FIGS. 13A-13C is coupled to the structure of FIGS. 14A-14C with the die attach material 114. In addition, the bond wires 110 and 118 are coupled as described above and as shown in FIGS. 1A-1C.

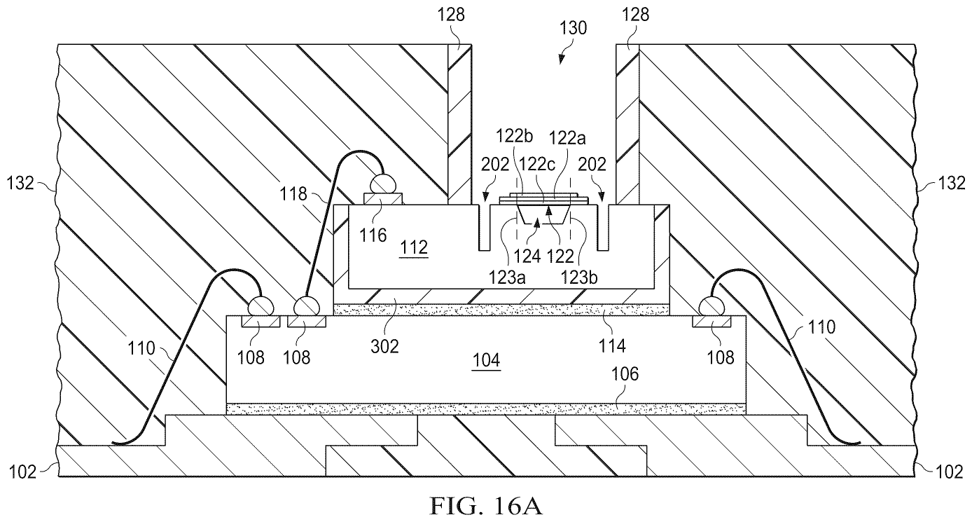

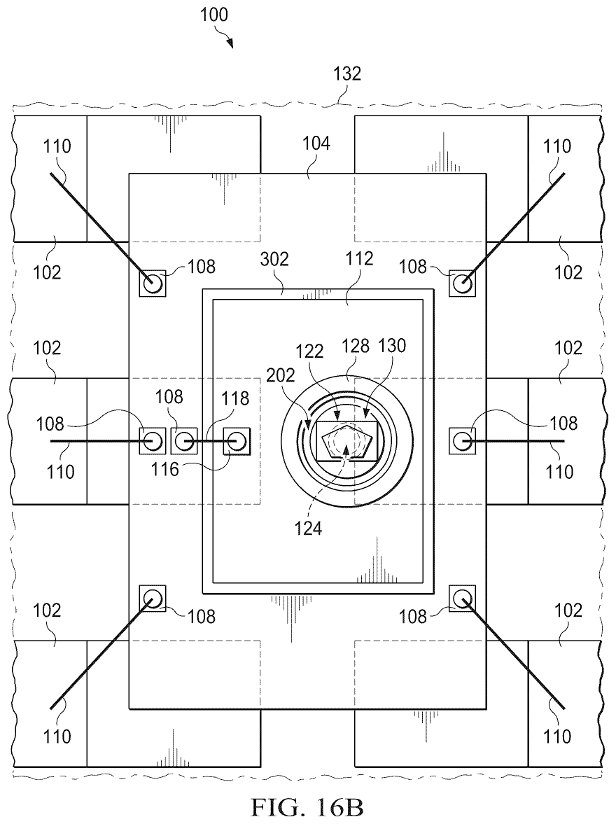

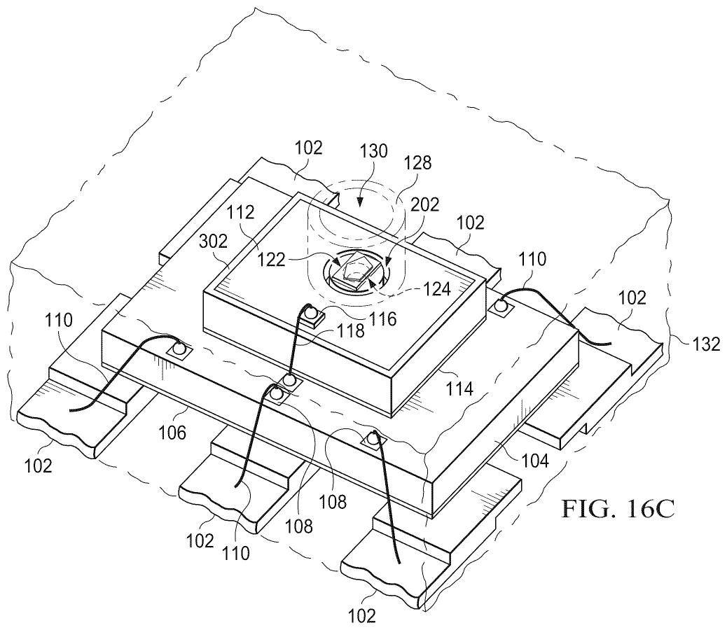

The method 500 includes applying a mold compound to the portion of the lead frame, the second semiconductor die, and the first semiconductor die (520). The cylindrical polymer wall of the multiple cylindrical polymer walls that is coupled to the first semiconductor die defines a cavity from which the mold compound is absent (520). FIGS. 16A-16C are profile cross-sectional, top-down, and perspective views of the structure of FIGS. 15A-15C, except that the mold compound 132 is applied contacting portions of surfaces of the structure in FIGS. 15A-15C. Specifically, the mold compound 132 physically contacts all surfaces of the structure in FIGS. 15A-15C except for the inner surface of the polymer wall 128. When the mold chase lid is lowered onto the structure of FIGS. 15A-15C, the mold chase lid forms a seal with the top surface of the polymer wall 128, thereby preventing the mold compound 132 from entering the cavity 130.

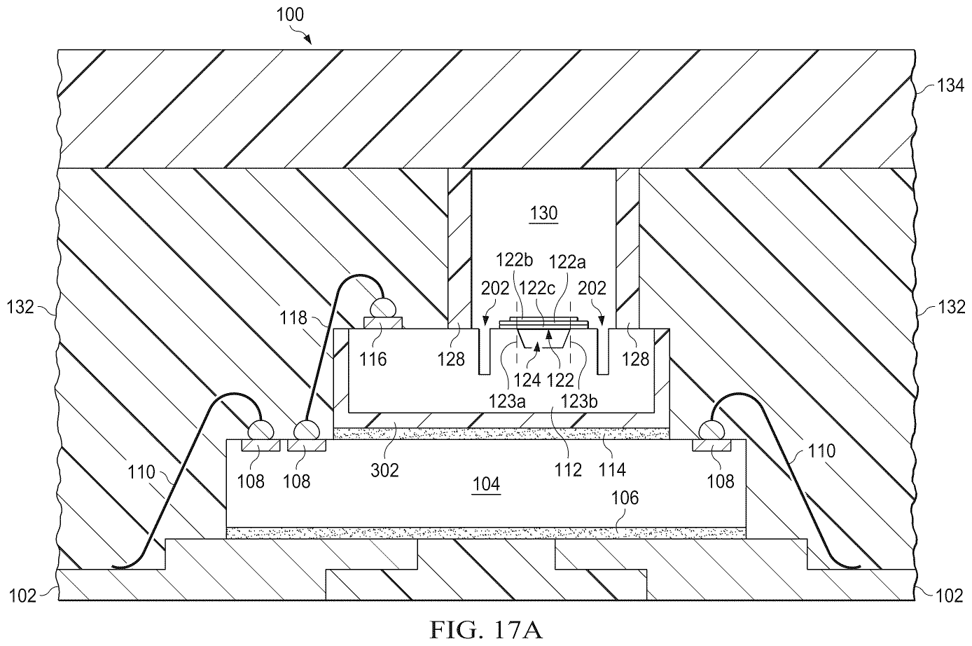

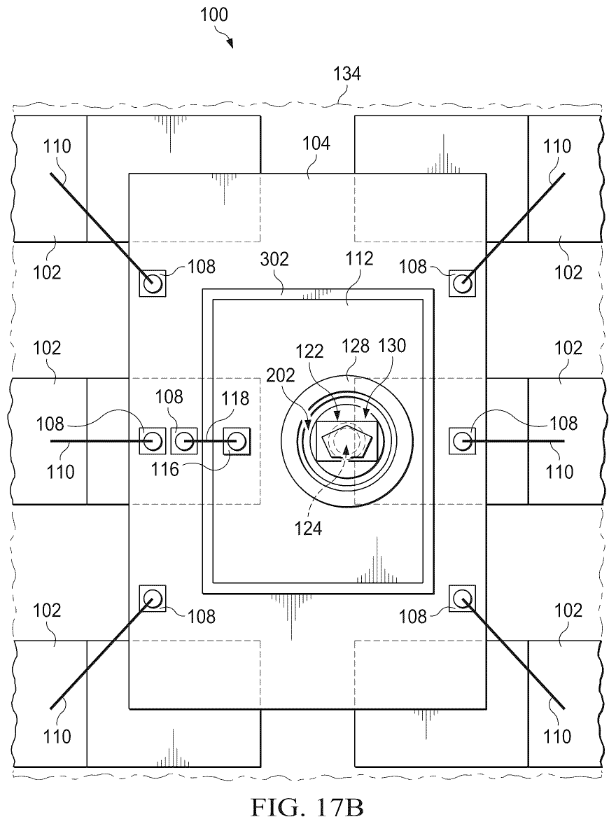

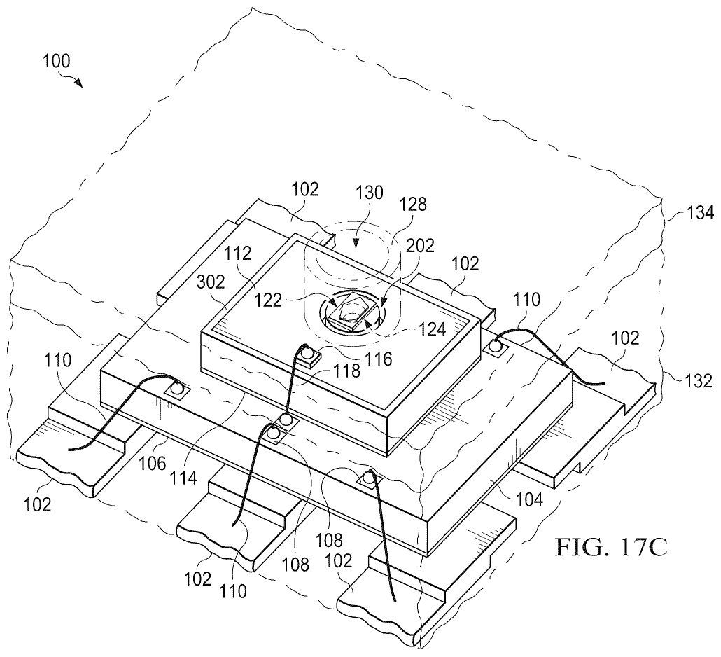

The method 500 includes coupling an epoxy film to a top surface of the cylindrical polymer wall that is coupled to the first semiconductor die and to a top surface of the mold compound (522). FIGS. 17A-17C are profile cross-sectional, top-down, and perspective views of the structure of FIGS. 16A-16C, except that the epoxy film 134 is applied as shown in FIGS. 1A-1C.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” “conductive terminal,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a portion of a lead frame;
a controller die coupled to the portion of the lead frame, the controller die including a first device side in which first circuitry is formed and a first non-device side opposite the first device side;
a bulk acoustic wave (BAW) resonator die coupled to the controller die by a bond wire, the BAW resonator die having a second device side in which second circuitry is formed and a second non-device side opposite the second device side, the BAW resonator die including a cavity under the second circuitry;
a polymer wall contacting the second device side and circumscribing the second circuitry; and
a mold compound contacting an exterior of the polymer wall and absent from a cavity defined at least in part by the polymer wall.

2. The semiconductor package of claim 1, further comprising a third semiconductor die coupled to the BAW resonator die by a member extending along a perimeter of the third semiconductor die, a bottom surface of the third semiconductor die facing the second circuitry and at least partially defining a cavity above the second circuitry.

3. The semiconductor package of claim 1, wherein the BAW resonator die has fewer bond pads than the controller die.

4. The semiconductor package of claim 1, further comprising a polymer coat covering the second non-device side and four lateral surfaces of the BAW resonator die that are orthogonal to the second non-device side, the polymer coat having a thickness ranging from 10 microns to 15 microns.

5. The semiconductor package of claim 1, further comprising an epoxy film vertically distanced from the second circuitry, the BAW resonator die in between the epoxy film and the controller die.

6. The semiconductor package of claim 5, wherein the epoxy film has a thickness ranging from 50 microns to 80 microns.

7. The semiconductor package of claim 1, further comprising a trench in the BAW resonator die, the trench circumscribing the second circuitry.

8. The semiconductor package of claim 7, wherein the trench has a depth that is at least 20% of a thickness of the BAW resonator die.

9. The semiconductor package of claim 7, wherein the trench is in fluid communication with a cavity that is above the second circuitry.

10. A semiconductor package, comprising:
a portion of a lead frame;
a first semiconductor die coupled to the portion of the lead frame, the first semiconductor die having a first device side in which first circuitry is formed and a first non-device side opposite the first device side;
a second semiconductor die coupled to the first device side of the first semiconductor die, the second semiconductor die having a second device side in which second circuitry is formed and a second non-device side opposite the second device side, the second semiconductor die having four lateral surfaces orthogonal to the second device side;
a polymer coat physically contacting the four lateral surfaces and the second non-device side, the polymer coat not covering an entirety of the second device side;
a trench in the second device side and circumscribing the second circuitry;
a cavity in the second semiconductor die and below the second circuitry;
a polymer wall circumscribing the trench and extending vertically away from the second device side;
a mold compound covering the first and second semiconductor dies and physically contacting an outer surface of the polymer wall; and
an epoxy film contacting a top surface of the polymer wall and a top surface of the mold compound.

11. The semiconductor package of claim 10, wherein the polymer coat does not cover an entirety of the second device side.

12. The semiconductor package of claim 10, wherein the trench circumscribes the second circuitry.

13. The semiconductor package of claim 10, wherein the cavity extends from a first vertical plane to a second vertical plane in a profile cross-sectional view, and wherein the second circuitry extends horizontally beyond the first and second vertical planes in the profile cross-sectional view.

14. The semiconductor package of claim 10, wherein the mold compound is absent from a second cavity defined by the polymer wall and the epoxy film.

15. The semiconductor package of claim 10, wherein the second semiconductor die is a bulk acoustic wave (BAW) die.

16. The semiconductor package of claim 10, wherein the cavity has a vertical depth in a side view ranging from 40 microns to 60 microns.

17. The semiconductor package of claim 10, wherein the cavity has a horizontal width in a top view ranging from 200 microns to 300 microns.

18. The semiconductor package of claim 10, wherein the polymer coat has a thickness ranging from 10 microns to 15 microns.

19. The semiconductor package of claim 10, wherein the polymer wall has a height ranging from 100 microns to 150 microns.

20. The semiconductor package of claim 10, wherein the epoxy film has a thickness ranging from 50 microns to 80 microns.

21. A method for manufacturing a semiconductor package, comprising:
etching through a thickness of a semiconductor wafer using a patterned photoresist to form multiple semiconductor dies separated by multiple gaps, each of the multiple semiconductor dies having a device side in which circuitry is formed and a non-device side opposite the device side, each of the multiple semiconductor dies including a trench circumscribing the circuitry and a cavity in that semiconductor die between the circuitry of that semiconductor die and the non-device side of that semiconductor die;
depositing a polymer material into the multiple gaps and on the non-device sides of the semiconductor dies;
dicing through the polymer material in one of the multiple gaps to produce a first semiconductor die separate from the remaining ones of the multiple semiconductor dies;
coupling a second semiconductor die to a portion of a lead frame;
coupling the first semiconductor die to the second semiconductor die; and
applying a mold compound to the portion of the lead frame, the second semiconductor die, and the first semiconductor die.

22. The method of claim 21, further comprising:
depositing a polymer member on the device sides of the semiconductor dies;
patterning the polymer member to produce multiple cylindrical polymer walls, each of the multiple cylindrical polymer walls circumscribing the circuitry of a different one of the multiple semiconductor dies, the cylindrical polymer wall of the multiple cylindrical polymer walls that is coupled to the first semiconductor die defining a cavity from which the mold compound is absent; and
coupling an epoxy film to a top surface of the cylindrical polymer wall that is coupled to the first semiconductor die and to a top surface of the mold compound.

23. The method of claim 22, wherein the depositing the polymer material comprises performing a spin coating process.

24. The method of claim 22, wherein the cylindrical polymer wall that is coupled to the first semiconductor die circumscribes the trench.

25. The method of claim 22, wherein the polymer material in between the first semiconductor die and the mold compound has a thickness ranging between 10 microns and 15 microns.

26. The method of claim 22, wherein the epoxy film has a thickness ranging from 50 microns to 80 microns.
